(19) United States
(12) Patent Application Publication
(10) Pub. No.: US 2021/0159260 A1
(43) Pub. Date: May 27, 2021

(54) PHOTOELECTRIC CONVERSION APPARATUS, METHOD FOR MANUFACTURING PHOTOELECTRIC CONVERSION APPARATUS, AND EQUIPMENT

(71) Applicant: CANON KABUSHIKI KAISHA, Tokyo (JP)

(72) Inventor: Yasushi Nakata, Kanagawa (JP)

(21) Appl. No.: 17/102,582

(22) Filed: Nov. 24, 2020

(30) Foreign Application Priority Data
Nov. 26, 2019 (JP) 2019-213317

(51) Int. Cl. H01L 27/146; H04N 5/3745

(52) U.S. Cl. CPC H01L 27/14623; H01L 27/14685; H01L 27/14643; H04N 5/37452; H01L 27/1464; H01L 27/14603

(57) ABSTRACT

Provided is a photoelectric conversion apparatus including a semiconductor layer having a pixel region including a photoelectric conversion unit and a light-shielding member disposed in the pixel region. The semiconductor layer has a main surface and a trench continuous with the main surface, the main surface including a light-receiving surface of the photoelectric conversion unit. The light-shielding member is disposed in the trench. The light-shielding member includes a first section and a second section that is closer to the main surface than the first section. The second section has a width that is greater than the width of the first section. The second section has a height that is greater than the width of the first section.

### BACKGROUND OF THE INVENTION

### Field of the Invention

The present invention relates to a photoelectric conversion apparatus, a method for manufacturing a photoelectric conversion apparatus, and equipment.

### Description of the Related Art

Imaging devices (photoelectric conversion apparatuses) such as CMOS image sensors and CCD image sensors are widely used for digital still cameras and digital video cameras, for example. A photoelectric conversion apparatus includes a charge holding portion that temporarily holds the charges converted by a photoelectric conversion unit at a position separate from the photoelectric conversion unit. Specifically, the charge holding portion may be used as a floating diffusion portion (hereinafter referred to as FD portion), which is the input node of an amplifier circuit, and as an element for holding charges in global shutter operation, in which the charges of all pixels are simultaneously held.

When a charge holding portion and a photoelectric conversion unit are formed in the same semiconductor substrate, light may incident on the charge holding portion holding charges and thus generate optical noise. Japanese Patent Application Publication No. 2013-65688 discloses a solution to the generation of optical noise. Specifically, this publication discloses a light-shielding wall formed between a photoelectric conversion unit and a charge holding portion.

Japanese Patent Application Publication No. 2015-32640 discloses a light-shielding portion provided around the photoelectric conversion elements of a solid state imaging device. The light-shielding portion includes light-shielding regions, which are located at the sides of the photoelectric conversion elements that face toward the light-receiving surfaces, and element isolation regions, which extend from the light-shielding regions into the areas between the photoelectric conversion elements in the depth direction.

Japanese Patent Application Publication No. 2013-65688 discloses a configuration including a light-shielding wall between a photoelectric conversion unit and a charge holding portion as a solution to optical noise generation. However, such a light-shielding wall may reduce the area of the region for the photoelectric conversion unit and compromise the sensitivity. Further, a light-shielding wall may limit the size reduction of the photoelectric conversion apparatus.

### SUMMARY OF THE INVENTION

An object of the present invention is to provide a photoelectric conversion apparatus that can achieve a higher sensitivity and a smaller size.

One aspect of the disclosure is a photoelectric conversion apparatus comprising: a semiconductor layer having a pixel region including a photoelectric conversion unit; and a light-shielding member disposed in the pixel region, wherein the semiconductor layer has a main surface and a trench continuous with the main surface, the main surface including a light-receiving surface of the photoelectric conversion unit, the light-shielding member is disposed in the trench, the light-shielding member includes a first section and a second section that is closer to the main surface than the first section, the second section has a width that is greater than a width of the first section, and the second section has a height that is greater than the width of the first section.

Another aspect of the disclosure is a method for manufacturing a photoelectric conversion apparatus, the method comprising the steps of: forming a trench by etching a semiconductor layer from a main surface side of the semiconductor layer, the semiconductor layer having a pixel region including a photoelectric conversion unit; and embedding a metal material in the trench, wherein the trench includes a first trench and a second trench that is disposed on the main surface side of the first trench, the second trench has a width that is greater than a width of the first trench, and the second trench has a height that is greater than the width of the first trench.

Yet another aspect of the disclosure is a method for manufacturing a photoelectric conversion apparatus, the method comprising the steps of: forming a trench by etching a semiconductor layer from a main surface side of the semiconductor layer, the semiconductor layer having a pixel region including a photoelectric conversion unit; and embedding a metal material in the trench, wherein the trench includes a first trench and a second trench that is disposed on the main surface side of the first trench, and the step of forming the trench includes a step of forming the second trench; and a step of forming the first trench on a bottom surface of the second trench.

According to the present disclosure, a photoelectric conversion apparatus that can achieve a higher sensitivity and a smaller size can be achieved.

Further features of the present invention will become apparent from the following description of exemplary embodiments with reference to the attached drawings.

### BRIEF DESCRIPTION OF THE DRAWINGS

FIGS. 1A and 1B are cross-sectional views of a pixel of a first embodiment;

FIG. 2 is a plan view of the pixel of the first embodiment;

FIGS. 3A and 3B are cross-sectional views of a pixel of a second embodiment;

FIG. 4 is a plan view of the pixel of the second embodiment;

FIGS. 5A to 5F are cross-sectional views of a pixel illustrating Manufacturing Process 1 of a photoelectric conversion apparatus of the first embodiment;

FIGS. 6A to 6F are cross-sectional views of a pixel illustrating Manufacturing Process 2 of a photoelectric conversion apparatus of the first embodiment;

FIG. 7 is a cross-sectional view of a light-shielding member of a modification; and

FIG. 8 is a diagram illustrating equipment of a third embodiment.

### DESCRIPTION OF THE EMBODIMENTS

Semiconductor apparatuses of embodiments are now described with reference to the drawings. However, the present invention is not limited to these embodiments.

### First Embodiment

A photoelectric conversion apparatus of the first embodiment is a CMOS image sensor. A CMOS image sensor typically includes a pixel array portion, a vertical driving portion, a column processing portion, a horizontal driving portion, and a system control portion. The pixel array portion includes a two-dimensional array of unit pixels, each including a photoelectric conversion element for generating and accumulating photo-generated charges in amount proportional to the amount of incident light. Hereinafter, a unit pixel is simply referred to as a pixel, and the description focuses on the photoelectric conversion unit region and the charge holding portion region. When a photoelectric conversion apparatus is used as an optical sensor instead of an image sensor, the photoelectric conversion apparatus does not have to include multiple pixels and it is sufficient that the photoelectric conversion apparatus includes at least one pixel.

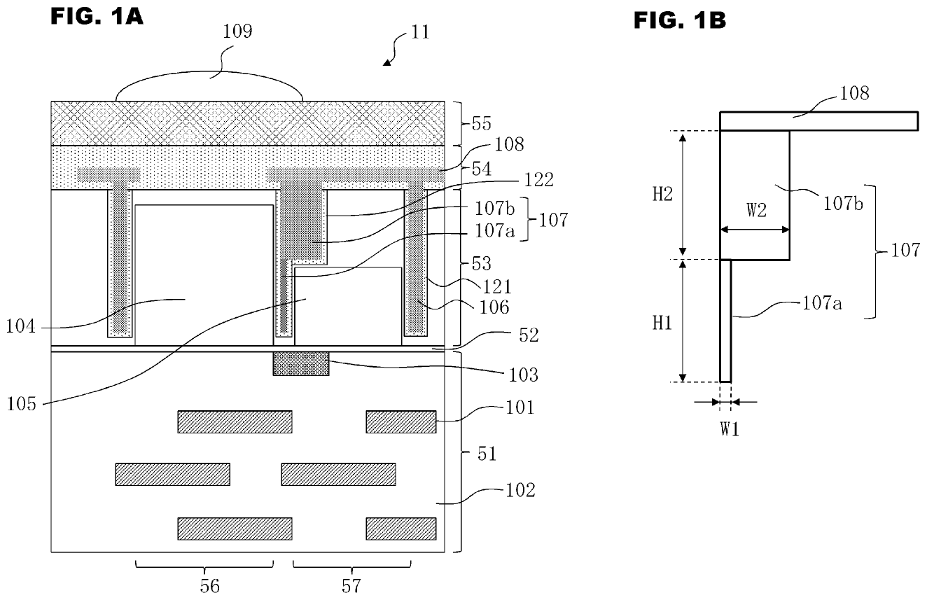

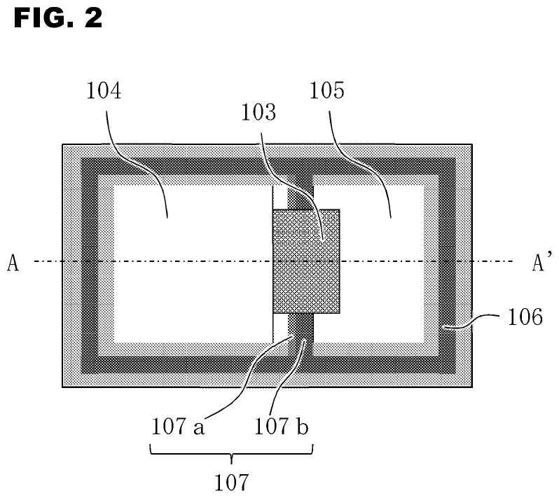

FIG. 1A is a cross-sectional view of a pixel of the first embodiment. FIG. 1B is an enlarged view of a light-shielding member 107. FIG. 2 is a plan view of the pixel of the first embodiment as viewed opposite to the light incident direction. FIG. 1A is a cross-sectional view taken along line A-A′ in FIG. 2.

As shown in FIG. 1A, a pixel 11 includes a wiring layer 51, an oxide film 52, a semiconductor substrate 53, a dielectric material layer 54, a color filter layer 55, and an on-chip lens 109, which are layered in this order from the bottom as viewed in FIG. 1A. FIG. 1A shows one pixel 11, but multiple pixels 11 may have the structure shown in FIG. 1A. The region of the semiconductor substrate 53 in which the pixel 11 is formed is referred to as a pixel region. The region of the semiconductor substrate 53 in which a photoelectric conversion unit 104 is formed is referred to as a photoelectric conversion unit region 56, and the region of the semiconductor substrate 53 in which a charge holding portion 105 is formed is referred to as a charge holding portion region 57. Although not shown, the pixel 11 also has a floating diffusion region (hereinafter referred to as FD) and an amplification transistor that outputs a signal according to the charges accumulated in the FD. The charge holding portion 105 corresponds to a first charge holding portion, and the FD corresponds to a second charge holding portion. The semiconductor substrate 53 generally has two surfaces. In the present embodiment, for convenience of illustration, the upper surface (main surface) as viewed in FIG. 1A is the first surface. The lower surface as viewed in FIG. 1A is the second surface. As shown in FIG. 1A, the wiring layer 51 is located at the second surface side of the semiconductor substrate 53. Light enters the semiconductor substrate 53 from the first surface side, and the first surface is the main surface including the light-receiving surface of the photoelectric conversion unit 104. That is, the photoelectric conversion apparatus of the present embodiment is a back-illuminated CMOS image sensor, which receives incident light on the surface opposite to the surface where the wiring layer of the semiconductor substrate 53 is located.

The photoelectric conversion unit 104 converts the light received through the on-chip lens 109 into charges. The charge holding portion 105 temporarily holds the charges transferred from the photoelectric conversion unit 104. The voltage applied to the transfer gate 103 controls the transfer of charges from the photoelectric conversion unit 104 to the charge holding portion. In this embodiment, the charge holding portion 105 holds electrons as signal charges. As such, the photoelectric conversion unit 104 and the charge holding portion 105 each include an N-type semiconductor region in the semiconductor substrate 53. The N type is the conductivity type of a semiconductor region that uses electrons, which have the same polarity as the signal charges, as the majority carriers. In a configuration that uses holes as signal charges, the photoelectric conversion unit 104 and the charge holding portion 105 each include a P-type semiconductor region in the semiconductor substrate 53.

The wiring layer 51 includes multiple layers of wires 101 and is formed on the side opposite to the light-receiving surface of the photoelectric conversion unit 104. The light-receiving surface of the photoelectric conversion unit 104 is a part of the first surface of the semiconductor substrate 53. The wiring layer 51 is formed by burying multiple wires 101 in an interlayer insulating film 102. The wires 101 transmit and hold the control signals used to read out charges from the photoelectric conversion unit 104, and the signals converted from the charges of the photoelectric conversion unit 104.

A substrate support (not shown) may be placed under the wiring layer 51. For example, an element such as a transistor (not shown) may be formed in the wiring layer 51 and the semiconductor substrate 53 to serve as a charge readout circuit, and a circuit for AD conversion after readout and a circuit for the subsequent step may be formed in the substrate support. That is, the photoelectric conversion apparatus of the present embodiment may be a stacked image sensor. Such a configuration provides a high-speed, high-performance image sensor.

Further, the region of the wiring layer 51 that is located between the photoelectric conversion unit 104 and the charge holding portion 105 includes a transfer gate 103, which is disposed at the semiconductor substrate 53 with the oxide film 52 arranged in between. The transfer gate 103 is disposed at the second surface side of the semiconductor substrate 53. Applying a predetermined voltage to the transfer gate 103 transfers the charges accumulated in the photoelectric conversion unit 104 to the charge holding portion 105. The oxide film 52 has insulation properties and forms the gate insulating film of the transfer gate 103. That is, the N-type semiconductor region of the photoelectric conversion unit 104, the transfer gate 103, and the N-type semiconductor region of the charge holding portion 105 form a MOS transistor.

The semiconductor substrate 53 includes a light-shielding film 108, a light-shielding member 106, and a light-shielding member 107, which are formed by etching and covered by the dielectric material layer 54. The light-shielding member 106 and the light-shielding member 107 can also be referred to as light-shielding walls. The light-shielding film 108, the light-shielding member 106, and the light-shielding member 107 are made of a light-shielding material. The light-shielding member 107 has a step-shaped dual-damascene structure including a first section 107a and a second section 107b. The second section 107b is closer to the first surface (main surface, light-receiving surface) than the first section 107a. As shown in the enlarged view of FIG. 1B, the width W2 of the second section 107b is greater than the width W1 of the first section 107a.

The semiconductor substrate (semiconductor layer) 53 includes grooves (trenches) continuous with the main surface (first surface) including the light-receiving surface of the photoelectric conversion unit 104. The light-shielding members 106 and 107 are disposed in the trenches formed in the pixel region within the semiconductor substrate (semiconductor layer) 53. The light-shielding members 106 and 107 surround the photoelectric conversion unit 104 and the charge holding portion 105 and extend in a direction perpendicular to the light-shielding film 108 (the direction normal to the light-shielding film 108) to a predetermined depth. The semiconductor substrate 53 has the trenches for accommodating the light-shielding members 106 and 107.

The trench that accommodates the light-shielding member 107 includes a first trench and a second trench, which is closer to the main surface (first surface, light-receiving surface) than the first trench. The second trench has a width that is greater than the width of the first trench. The height of the second trench is greater than the width of the first trench. To simplify the description, the section of the light-shielding member 107 that is disposed in the first trench (first section) is also referred to as a first trench section 107a, and the section of the light-shielding member 107 that is disposed in the second trench (second section) is also referred to as a second trench section 107b. The trench accommodating the light-shielding member 106 has a uniform width.

When the light-shielding members 106 and 107 are made of a conductive material, insulating materials 121 and 122 may be embedded in the trenches in addition to the light-shielding members 106 and 107 to insulate these light-shielding members 106 and 107 from the semiconductor substrate 53. That is, the insulating materials 121 and 122 may be placed between the light-shielding members 106 and 107 and the surfaces defining the trenches (the semiconductor substrate 53). When the insulating materials 121 and 122 are embedded between the light-shielding members 106 and 107 and the surfaces defining the trenches, the width of each light-shielding member 106, 107 is smaller than the width of the trench by the thickness of each of the insulating materials 121, 122. The light-shielding member formed between the photoelectric conversion unit 104 and the charge holding portion 105 is referred to as the light-shielding member 107, and the other section is referred to as the light-shielding member 106. The light-shielding members 106 and 107 may be primarily composed of copper, tungsten, or aluminum, for example. The first trench section 107a and the second trench section 107b of the light-shielding member 107 may be made of the same material or different materials.

In the present embodiment, only the first trench section 107a is formed between the photoelectric conversion unit 104 and the charge holding portion 105. The charge holding portion 105 is smaller in height than the photoelectric conversion unit 104, and the second trench section 107b is formed at a position higher than the upper part of the charge holding portion 105. In other words, the distance between the surface of the charge holding portion 105 that faces toward the light-receiving surface and the light-receiving surface of the semiconductor substrate 53 is greater than the distance between the surface of the photoelectric conversion unit 104 that faces toward the light-receiving surface and the light-receiving surface of the semiconductor substrate 53. The surface of the charge holding portion 105 that faces toward the light-receiving surface is closer the light-receiving surface than the surface of the second trench section 107b on the opposite side to the side that faces the light-receiving surface. Thus, only the first trench section 107a is disposed between the photoelectric conversion unit 104 and the charge holding portion 105, allowing for a shorter distance between the photoelectric conversion unit 104 and the charge holding portion 105. The second trench section 107b covers at least a part of the side of the charge holding portion 105 that faces toward the light-receiving surface.

Further, in a top view, the distance between the center of the first trench section 107a and the photoelectric conversion unit 104 is smaller than the distance between the center of the second trench section 107b and the photoelectric conversion unit 104. This allows for a shorter distance between the photoelectric conversion unit 104 and the charge holding portion 105. In this embodiment, the side surface of the first trench section 107a that faces toward the photoelectric conversion unit 104 is flush with the side surface of the second trench section 107b that faces toward the photoelectric conversion unit 104.

Since the light-shielding members 106 and 107 are formed by etching the semiconductor substrate 53, the performance of the manufacturing apparatus affects the width and height of the etched light-shielding members. In general, for etching with a width of about 0.1 μm to 0.3 μm, the limit of the height to width ratio (height/width ratio, aspect ratio) is about 15 to 20.

In this embodiment, the light-shielding members 106 and 107 substantially have the same height. In other words, the height of the light-shielding member 106 is substantially the same as the height obtained by adding the height H1 of the first trench section 107a to the height H2 of the second trench section 107b. The light-shielding member 106 is formed within the performance limit of the manufacturing apparatus, and the width of the light-shielding member 106 can be minimized by using the height to width ratio of the performance limit of the manufacturing apparatus. The light-shielding member 107, which includes the first and second trench sections 107a and 107b of different widths, is formed in multiple etching steps. Thus, it is possible to form the first trench section 107a with the height to width ratio of the performance limit of the manufacturing apparatus. That is, the difference in height between the first trench section 107a and the light-shielding member 106 allows the first trench section 107a to have a smaller width than the light-shielding member 106 accordingly.

For example, when the thickness of the semiconductor substrate 53 is about 3.0 μm and the performance limit of the manufacturing apparatus is a height to width ratio of about 15, the width of the light-shielding member 106 is about 0.2 μm. In contrast, the first trench section 107a can have a width W1 of about 0.1 μm when the height H2 of the second trench section 107b is about 1.5 μm, which is half the thickness of the semiconductor substrate 53. That is, forming the light-shielding member with step-shaped two trench sections, instead of with one trench section, allows the first trench section 107a (i.e., the lowest trench section) to have a smaller width. The width W1 of the first trench section 107a is not limited to the above value, and may be any value according to the sizes of the semiconductor substrate 53 and other components in its vicinity. The first trench section 107a is preferably formed to have the aspect ratio of the performance limit of the manufacturing apparatus, but the second trench section 107b has a smaller aspect ratio than the first trench section 107a. That is, the height to width ratio (H1/W1) of the first trench section 107a may be greater than the height to width ratio (H2/W2) of the second trench section 107b.

The size of each component is not limited to the range described above. For example, the thickness of the semiconductor substrate 53 may be at least 1.5 μm and not more than 4.5 μm. The width of the light-shielding member 106 may be at least 0.1 μm and not more than 0.3 μm. The width W1 of the first trench section 107a may be at least 0.05 μm and not more than 0.15 μm.

The smaller width W1 of the first trench section 107a allows for a larger area of the photoelectric conversion unit 104 and a shorter distance between the photoelectric conversion unit 104 and the charge holding portion 105. This enables the photoelectric conversion apparatus to have a higher sensitivity and a smaller size. By forming two or more step-shaped trench sections, the width of the first trench section 107a closest to the wiring layer 51 can be further reduced.

The first trench section 107a can have a smaller width W1 when at least the height H2 of the second trench section 107b is greater than the width W1 of the first trench section 107a. A smaller width W1 of the first trench section 107a can be achieved by reducing the height H1 of the first trench section 107a. This is achieved by increasing the height H2 of the second trench section 107b. When the height H2 of the second trench section 107b is greater than the width W1 of the first trench section 107a, the width W1 of the first trench section 107a can be reduced accordingly. By increasing the proportion of the height H2 of the second trench section 107b in the overall height (H1+H2) of the light-shielding member 107, the width W1 of the first trench section 107a can be reduced accordingly. For example, the height H1 of the first trench section may be ¼ of the thickness of the semiconductor substrate 53, and the height H2 of the second trench section may be ¾ of the thickness of the semiconductor substrate. Alternatively, the height H1 of the first trench section may be ¾ of the thickness of the semiconductor substrate 53, and the height H2 of the second trench section may be ¼ of the thickness of the semiconductor substrate.

As described above, a smaller height H1 of the first trench section 107a, in other words, a larger height H2 of the second trench section 107b allows for a smaller width W1 of the first trench section 107a. As such, it is desirable that the distance between the surface of the charge holding portion 105 that faces toward the light-receiving surface (first surface) and the surface of the second trench section 107b that faces away from the light-receiving surface (faces toward the second surface) be as small as possible. Preferably, this distance is smaller than the width W1 of the first trench section 107a.

A smaller distance between the photoelectric conversion unit 104 and the charge holding portion 105 can increase the area of the photoelectric conversion unit 104. This suppresses optical noise and allows the pixel to have a higher sensitivity and a smaller size.

The second trench section 107b may cover the entire charge holding portion 105. This increases the thickness of the light-shielding member over the charge holding portion 105, improving the light-shielding performance. Moreover, since the second trench section 107b provides the function of the light-shielding film 108, the light-shielding film 108 can be omitted, thereby simplifying the process.

However, when the second trench section 107b covers the entire charge holding portion 105, the light entering through the gap between the transfer gate 103 and the light-shielding member 107 may be reflected on the lower surface of the second trench section 107b and incident on the charge holding portion 105. This may generate optical noise. For this reason, the width of the second trench section 107b may be set in a range that does not cause the light entering through the gap between the transfer gate 103 and the light-shielding member 107 to be reflected on the lower surface of the second trench section 107b. Accordingly, the light entering through the gap between the transfer gate 103 and the light-shielding member 107 can have a sufficient optical path length and is less likely to generate optical noise.

The width W2 of the second trench section 107b may be reduced as long as it is greater than the width W1 of the first trench section 107a. In case light enters through the gap between the transfer gate 103 and the light-shielding member 107, a smaller width W2 can reduce the light reflecting on the lower surface of the second trench section 107b and incident on the charge holding portion 105, thereby reducing optical noise.

The light-shielding film 108 is formed on the light-receiving surface side (the upper side as viewed in the drawing) of the semiconductor substrate 53, and blocks light from reaching the charge holding portion 105. The light-shielding film 108 covers at least a part of the charge holding portion 105, and preferably covers the entire charge holding portion 105. The state in which the light-shielding film 108 covers the charge holding portion 105 refers to the state in which the region of the charge holding portion 105 is located within the region of the light-shielding film 108 in a plan view. More preferably, the light-shielding film 108 covers the entire region except for the region of the photoelectric conversion unit 104. This further reduces the incident light reaching the charge holding portion 105.

Further, the light-shielding film 108, the light-shielding member 106, and the light-shielding member 107 may be made of a metal material such as tungsten, aluminum, or copper, so that the entry of incident light into the charge holding portion 105 is blocked more effectively. In the present embodiment, the light-shielding film 108, the light-shielding member 106, and the light-shielding member 107 are made of the same metal material.

When the light-shielding member 107 is made of a conductive material, charges cannot be transferred if the light-shielding member 107 is in contact with the transfer gate 103. It is thus necessary to provide a certain distance between the transfer gate 103 and the light-shielding member 107. The entire light-shielding member 107 may be separated from the transfer gate 103 or the surface of the semiconductor substrate 53. However, in this case, incident light may enter through the gap between the light-shielding member 107 and the surface of the semiconductor substrate 53 and into the charge holding portion 105. To limit the entry of incident light into the charge holding portion 105, the light-shielding member 107 preferably extends to the surface of the semiconductor substrate 53 in at least a part of the region other than the area directly above the transfer gate 103. This configuration reduces the possibility of the incident light obliquely entering the charge holding portion 105.

According to the present embodiment, the charge holding portion 105 is provided in each pixel and temporarily holds the charges converted by the photoelectric conversion unit 104. This allows for the global shutter function, which uses the same exposure timing for all pixels. Further, the light-shielding members 106 and 107 reduce the likelihood that light is incident on the charge holding portion 105 holding charges. This suppresses optical noise and therefore achieves high-quality image signals. Additionally, a thinner first trench section 107a is achieved by forming the light-shielding member 107 in a step shape, allowing for a shorter distance between the photoelectric conversion unit 104 and the charge holding portion 105, and a larger area of the photoelectric conversion unit 104. That is, the present embodiment enables the photoelectric conversion apparatus with the global shutter function to have both a higher sensitivity and a smaller size.

In the example shown in FIGS. 1A and 1B, the light-shielding member 106 is separated from the surface of the semiconductor substrate 53, but the light-shielding member 106 may also be in contact with the surface of the semiconductor substrate 53. This configuration reduces optical noise, which would otherwise occur due to crosstalk of light that has entered adjacent pixels.

The light-shielding member 107 of the present embodiment is also applicable to a rolling shutter photoelectric conversion apparatus. That is, even when the solid state imaging device does not include the charge holding portion 105, providing the step-shaped light-shielding member 107 between the photoelectric conversion unit 104 and the floating diffusion layer (FD portion) allows the photoelectric conversion apparatus to have a higher sensitivity and a smaller size. The FD portion is an example of a charge holding portion that holds the charges converted by the photoelectric conversion unit 104.

In the foregoing description, the conditions are described regarding the widths and heights of the first section (first trench section) 107a and the second section (second trench section) 107b of the light-shielding member 107. However, the conditions described above can also be considered as the conditions for the widths and heights of the trenches formed in the semiconductor substrate 53. For example, the width of the second trench may be greater than the width of the first trench. The height to width ratio (aspect ratio) of the first trench may be greater than the height to width ratio (aspect ratio) of the second trench. When the light-shielding member 107 is made of a metal material and the insulating material (dielectric material) 121 is placed between the light-shielding member 107 and the surfaces defining the trench, the width and thickness of the light-shielding member 107 are smaller than the width and thickness of the trench by the width and thickness of the insulating material 121. When the light-shielding member 107 is directly embedded in the trench without the insulating material 121, the light-shielding member 107 is equal to the trench in width and thickness. However, as long as the widths and heights of the first and second sections 107a and 107b of the light-shielding member 107 satisfy the relationship described above, the width and height of the trench can be in any relationship. For example, the trench may have a uniform width regardless of the height, and the second section of the light-shielding member on the main surface side may have a greater width than the first section in the trench.

### Second Embodiment

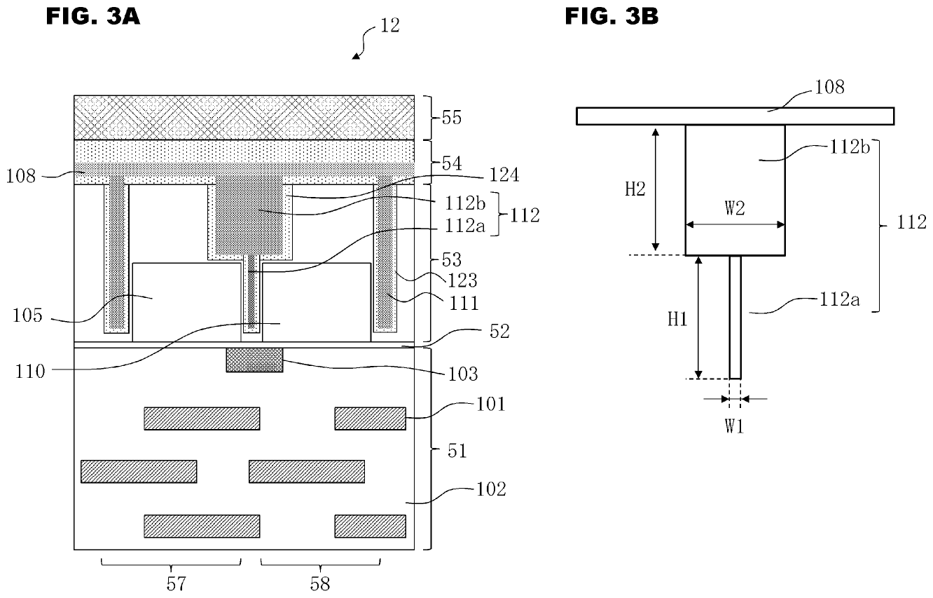

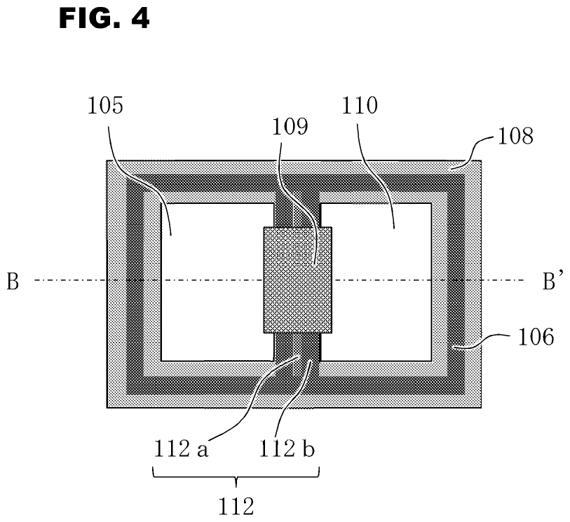

FIG. 3A is a cross-sectional view of a pixel of the second embodiment. FIG. 2B is an enlarged view of a light-shielding member 112. FIG. 4 is a plan view of the pixel of the second embodiment as viewed opposite to the light incident direction. FIG. 3A is a cross-sectional view taken along line B-B′ in FIG. 4.

As shown in FIG. 3A, a pixel 12 includes a wiring layer 51, an oxide film 52, a semiconductor substrate 53, a dielectric material layer 54, and a color filter layer 55, which are layered in this order from the bottom as viewed in FIG. 3A. FIG. 3A shows one pixel 11, but multiple pixels 11 may have the structure shown in FIG. 3A. The region of the semiconductor substrate 53 in which a charge holding portion 105 is formed is referred to as a charge holding portion region 57, and the region of the semiconductor substrate 53 in which a floating diffusion region (FD) 110 is formed is referred to as a FD region 58. Although not shown, the pixel 12 also has a photoelectric conversion unit that converts the received light into charges, a transfer gate that transfers the charges accumulated in the photoelectric conversion unit to the charge holding portion, an amplification transistor that outputs a signal according to the charges accumulated in the FD. The pixel 12 is a back-illuminated CMOS image sensor, in which light is incident on the surface of the semiconductor substrate 53, that is, the upper surface as viewed in FIG. 3A.

The charge holding portion 105 temporarily holds the charges transferred from the photoelectric conversion unit via the transfer gate. The FD 110 accumulates the charges transferred from the charge holding portion 105 via a transfer gate 103. Since the FD 110 also holds charges, the FD 110 can also be referred to as a charge holding portion.

The wiring layer 51 includes multiple layers of wires 101 and is formed on the side opposite to the light-receiving surface. A substrate support (not shown) may be placed under the wiring layer 51. For example, an element such as a transistor (not shown) may be formed in the wiring layer 51 and the semiconductor substrate 53 to serve as a charge readout circuit, and a circuit for AD conversion after readout and a circuit for the subsequent step may be formed in the substrate support. That is, the photoelectric conversion apparatus of the present embodiment may be a stacked image sensor. Such a configuration provides a high-speed, high-performance image sensor.

Further, the region of the wiring layer 51 that is located between the charge holding portion 105 and the FD 110 includes the transfer gate 103, which is located at the semiconductor substrate 53 with the oxide film 52 arranged in between. Applying a predetermined voltage to the transfer gate 103 transfers the charges temporarily held in the charge holding portion 105 to the FD 110. The oxide film 52 has insulation properties and insulates the surface of the semiconductor substrate 53.

The semiconductor substrate 53 includes a light-shielding film 108, a light-shielding member 111, and a light-shielding member 112, which are formed by etching and covered by the dielectric material layer 54. The light-shielding members 111 and 112 can also be referred to as light-shielding walls. The light-shielding film 108, the light-shielding member 111, and the light-shielding member 112 are made of a light-shielding material. The light-shielding member 112 has a step-shaped dual-damascene structure including a first section 112a and a second section 112b. The second section 112b is closer to the first surface (main surface, light-receiving surface) than the first section 112a. As shown in the enlarged view of FIG. 3B, the width W2 of the second section 112b is greater than the width W1 of the first section 112a.

The semiconductor substrate (semiconductor layer) 53 includes grooves (trenches) continuous with the main surface (first surface) including the light-receiving surface of the photoelectric conversion unit 104. The light-shielding members 111 and 112 are disposed in the trenches formed in the pixel region within the semiconductor substrate (semiconductor layer) 53. The light-shielding members 111 and 112 surround the charge holding portion 105 and the FD 110 and extend in a direction perpendicular to the light-shielding film 108 (the direction normal to the light-shielding film 108) to a predetermined depth. When the light-shielding members 111 and 112 are made of a conductive material, insulating materials 123 and 124 may be embedded in the trenches in addition to the light-shielding members 111 and 112 to insulate these light-shielding members 111 and 112 from the semiconductor substrate 53. When the insulating materials 123 and 124 are embedded between the light-shielding members 111 and 112 and the surfaces defining the trenches, the width of each light-shielding member 111, 112 is smaller than the width of the trench by the thickness of each of the insulating materials 123, 124. The light-shielding member formed between the charge holding portion 105 and the FD 110 is referred to as the light-shielding member 111, and the other section is referred to as the light-shielding member 112.

The trench that accommodates the light-shielding member 112 includes a first trench and a second trench, which is closer to the main surface (first surface, light-receiving surface) than the first trench. The second trench has a width that is greater than the width of the first trench. The height of the second trench is greater than the width of the first trench. To simplify the description, the section of the light-shielding member 112 that is located in the first trench (first section) is also referred to as a first trench section 112a, and the section of the light-shielding member 112 that is located in the second trench (second section) is also referred to as a second trench section 112b. The trench accommodating the light-shielding member 111 has a uniform width.

Since the light-shielding members 111 and 112 are formed by etching the semiconductor substrate 53, the performance of the manufacturing apparatus affects the width and height of the etched light-shielding members. In general, for etching with a width of about 0.1 μm to 0.3 μm, the limit of the height to width ratio (height/width ratio, aspect ratio) is about 15 to 20.

In this embodiment, the light-shielding members 111 and 112 substantially have the same height. In other words, the height of the light-shielding member 111 is substantially the same as the height obtained by adding the height of the first trench section 112a to the height of the second trench section 112b. The light-shielding member 111 is formed within the performance limit of the manufacturing apparatus, and the width of the light-shielding member 111 can be minimized by using the height to width ratio of the performance limit of the manufacturing apparatus. The light-shielding member 112, which includes the first and second trench sections 112a and 112b of different widths, is formed in multiple etching steps. Thus, it is possible to form the first trench section 112a with the height to width ratio of the performance limit of the manufacturing apparatus. That is, the difference in height between the light-shielding member 111 and the light-shielding member (first trench section) 112a allows the light-shielding member 112a to have a smaller width than the light-shielding member 111 accordingly.

For example, when the thickness of the semiconductor substrate 53 is about 3.0 μm and the performance limit of the manufacturing apparatus is a height to width ratio of about 15, the width of the light-shielding member 111 is about 0.2 μm. In contrast, the first trench section 112a can have a width W1 of about 0.1 μm when the height H2 of the second trench section 112b is about 1.5 μm, which is half the thickness of the semiconductor substrate 53. That is, forming the light-shielding member with step-shaped two trench sections, instead of with one trench section, allows the first trench section 112a (i.e., the lowest trench section) to have a smaller width W1. The smaller width W1 of the first trench section 112a allows for a shorter distance between the charge holding portion 105 and the FD 110. This enables the photoelectric conversion apparatus to have a smaller size. By forming two or more step-shaped trench sections, the width of the first trench section 112a closest to the wiring layer 51 can be further reduced.

The size of each component is not limited to the range described above. For example, the thickness of the semiconductor substrate 53 may be at least 1.5 μm and not more than 4.5 μm. The width of the light-shielding member 111 may be at least 0.1 μm and not more than 0.3 μm. The width W1 of the first trench section 112a may be at least 0.05 μm and not more than 0.15 μm.

A smaller height H1 of the first trench section 112a, in other words, a greater height H2 of the second trench section 112b allows for a smaller width W1 of the first trench section 112a. As such, it is desirable that distance between the surfaces of the charge holding portion 105 and the FD 110 that face toward the light-receiving surface (first surface) and the surface of the second trench section 112b that faces away from the light-receiving surface (faces toward the second surface) be as small as possible. For example, the distance between the surface of the second trench section 112b that faces toward the second surface and the higher one of the surfaces of the charge holding portion 105 and the FD 110 that face toward the light-receiving surface is preferably smaller than the width W1 of the first trench section 112a.

The first trench section 112a can have a smaller width W1 when at least the height H2 of the second trench section 112b is greater than the width W1 of the first trench section 112a. As such, forming only the first trench section 112a between the charge holding portion 105 and the FD 110 allows for a further reduction in the distance between the charge holding portion 105 and the FD 110. By reducing the thicknesses of the charge holding portion 105 and the FD 110 in the direction of the transfer gate 103, the second trench section 112b can cover at least a part of the side of at least one of the charge holding portion 105 and the FD 110 that faces toward the light-receiving surface. This allows for a further reduction in the distance between the charge holding portion 105 and the FD 110.

The second trench section 112b may cover the entire charge holding portion 105 or the entire FD 110. This increases the thickness of the light-shielding member over the charge holding portion 105 or the FD 110, improving the light-shielding performance. Moreover, since the second trench section 112b provides the function of the light-shielding film 108, the light-shielding film 108 can be omitted, thereby simplifying the process.

The light-shielding film 108 is formed on the light-receiving surface side (the upper side as viewed in the drawing) of the semiconductor substrate 53, and blocks light from reaching the charge holding portion 105. The light-shielding film 108 covers at least a part of the charge holding portion 105 and the FD 110, and preferably covers the entire charge holding portion 105 and the entire FD 110. The state in which the light-shielding film 108 covers the charge holding portion 105 or the FD 110 refers to the state in which the region of the charge holding portion 105 or the FD 110 is located within the region of the light-shielding film 108 in a plan view.

Further, the light-shielding film 108, the light-shielding member 111, and the light-shielding member 112 may be made of a metal material such as tungsten, aluminum, or copper, so that the entry of incident light into the charge holding portion 105 and the FD 110 is blocked more effectively. In the present embodiment, the light-shielding film 108, the light-shielding member 111, and the light-shielding member 112 are made of the same metal material.

When the light-shielding member 112 is made of a conductive material, charges cannot be transferred if the light-shielding member 112 is in contact with the transfer gate 103. It is thus necessary to provide a certain distance between the transfer gate 103 and the light-shielding member 112. Although the entire light-shielding member 112 may be separated from the transfer gate 103 or the surface of the semiconductor substrate 53, the light-shielding member 112 preferably extends to the surface of the semiconductor substrate 53 in at least a part of the region other than the area directly above the transfer gate 103. This configuration reduces entry of stray light into the charge holding portion 105.

In the example shown in FIGS. 3A and 3B, the light-shielding member 111 is separated from the surface of the semiconductor substrate 53, but the light-shielding member 111 may also extend to the surface of the semiconductor substrate 53. This configuration reduces optical noise, which would otherwise occur due to crosstalk of light that has entered adjacent pixels.

In the present embodiment, the light-shielding members 111 and 112 limit entry of light into the charge holding portion 105. This suppresses optical noise and therefore achieves high-quality image signals. Additionally, a thinner first trench section 112a is achieved by forming the light-shielding member 112 in a step shape, allowing for a shorter distance between the charge holding portion 105 and the FD 110, and a larger area of the photoelectric conversion unit. That is, the present embodiment enables the photoelectric conversion apparatus with the global shutter function to have both a higher sensitivity and a smaller size.

The first embodiment may be combined with the second embodiment. The photoelectric conversion apparatus of such an embodiment may have multiple pixels each having a photoelectric conversion unit, a charge holding portion, and an FD. In this embodiment, the light-shielding member 107 of the first embodiment is placed between the photoelectric conversion unit and the charge holding portion, and the light-shielding member 112 of the second embodiment is placed between the charge holding portion and the FD.

Manufacturing Method 1

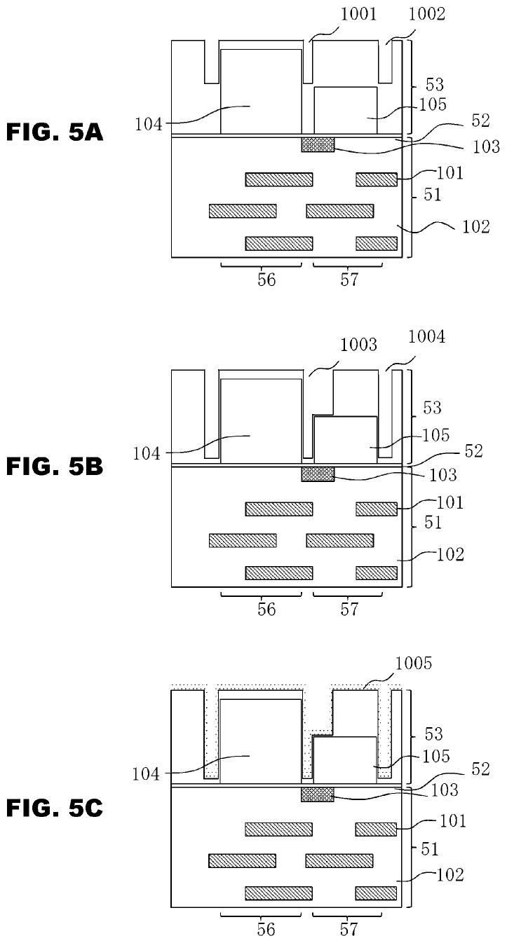

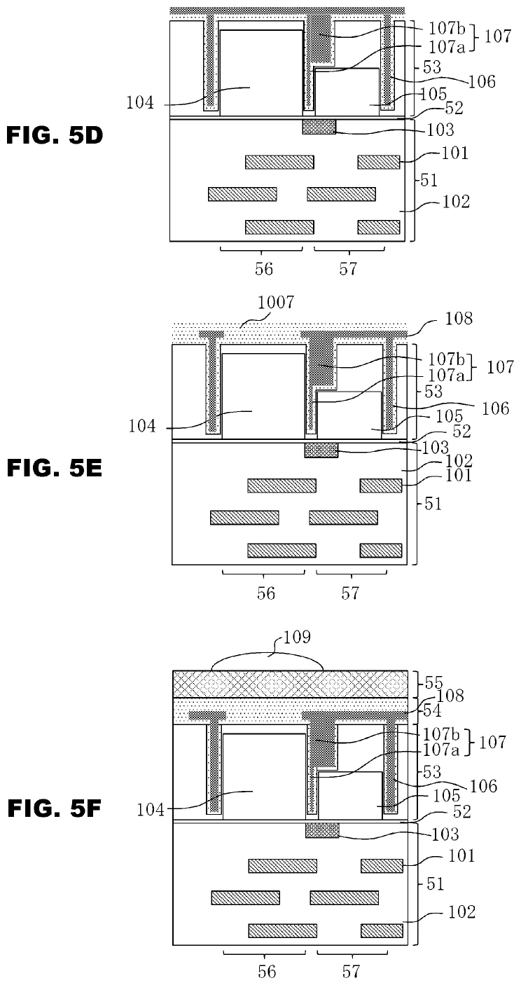

FIGS. 5A to 5F are cross-sectional views of a pixel illustrating Manufacturing Process 1 of a photoelectric conversion apparatus of the first embodiment. FIGS. 5A to 5F selectively show the manufacturing process that forms the light-shielding members 106 and 107 by etching.

As shown in FIG. 5A, a predetermined photoresist is patterned on the surface (main surface) that serves as the light-receiving surface of the semiconductor substrate 53, and a trench 1001 and a trench 1002 may be formed by reactive ion etching (RIE). In this step, the trench 1001 is formed by etching such that the trench 1001 has a width and a depth that are equal to the width and the depth of the first trench section 107a in the finished product. This step corresponds to the first step of the etching process.

As shown in FIG. 5B, a predetermined photoresist is then patterned on the semiconductor substrate 53 again, and a trench 1003 and a trench 1004 may be formed by RIE. The trench 1003 is formed by etching the region including the trench 1001 formed in the step of FIG. 5A to a width and a depth that are equal to the width and depth of the second trench section 107b in the finished product. This step corresponds to the second step of the etching process.

Then, as shown in FIG. 5C, a dielectric material layer 1005 is formed on the inner surfaces of the trenches 1003 and 1004 and the upper surface of the semiconductor substrate 53. The dielectric material layer 1005 is formed by chemical vapor deposition (CVD), atomic layer deposition (ALD), or other technique. As shown in FIG. 5D, a metal material, such as tungsten, aluminum, or copper, may be embedded by CVD in the trenches 1003 and 1004, whose inner surfaces are covered with the dielectric material layer 1005.

The light-shielding member 107 including the first trench section 107a and the second trench section 107b is thus formed.

Then, as shown in FIGS. 5E and 5F, a dielectric material layer 1007 may be formed by CVD, and a color filter 55 and a top lens 109 are sequentially formed.

This manufacturing method is also usable for the photoelectric conversion apparatus of the second embodiment.

Manufacturing Method 2

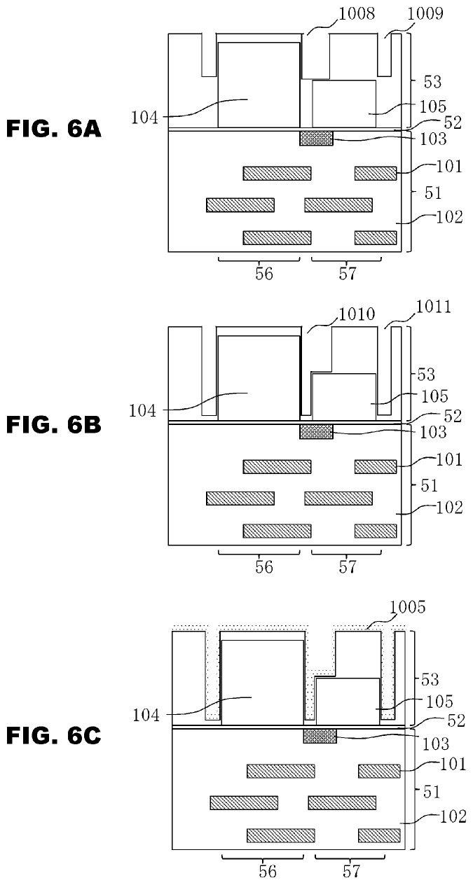

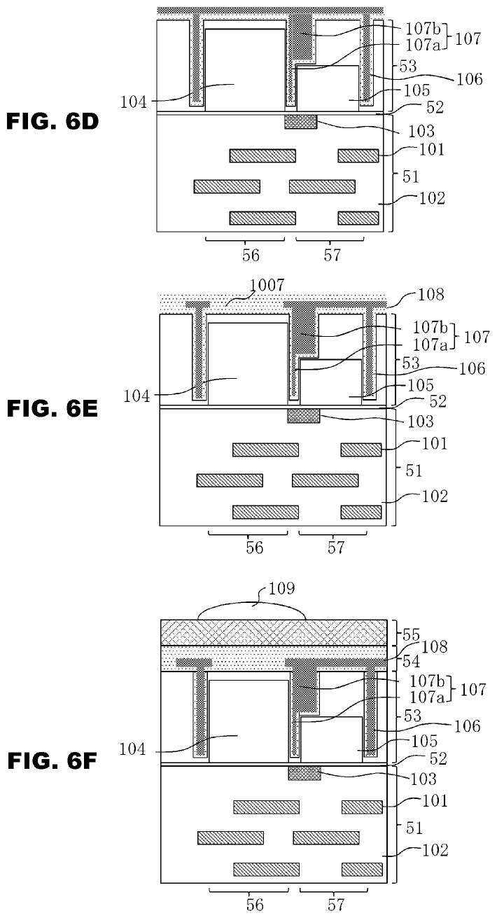

FIGS. 6A to 6F are cross-sectional views of a pixel illustrating Manufacturing Process 2 of a photoelectric conversion apparatus of the first embodiment. FIGS. 6A to 6F selectively show the manufacturing process that forms the light-shielding members 106 and 107 by etching.

As shown in FIG. 6A, a desired photoresist is patterned on the semiconductor substrate 53, and a trench 1008 and a trench 1009 may be formed by RIE. In this step, the trench 1008 is formed by etching such that the trench 1008 has a width and a depth that are equal to the width and the depth of the second trench section 107b in the finished product. This step corresponds to the first step of the etching process.

As shown in FIG. 6B, a predetermined photoresist is then patterned on the semiconductor substrate 53 again, and a trench 1010 and a trench 1011 may be formed by RIE. The trench 1010 is formed by etching the bottom surface of the trench 1008 formed in the step of FIG. 6A to the width and depth of the first trench section 107a in the finished product. This step corresponds to the second step of the etching process.

Then, as shown in FIG. 6C, a dielectric material layer 1005 is formed on the inner surfaces of the trenches 1010 and 1011 and the upper surface of the semiconductor substrate 53 by CVD, ALD, or other technique. As shown in FIG. 6D, a metal material, such as tungsten, aluminum, or copper, may be embedded by CVD in the trenches 1003 and 1004, whose inner surfaces are covered with the dielectric material layer 1005.

The light-shielding member 107 including the first trench section 107a and the second trench section 107b is thus formed.

Then, as shown in FIGS. 6E and 6F, a dielectric material layer 1007 may be formed by CVD, and a color filter 55 and a top lens 109 are sequentially formed.

This manufacturing method is also usable for the photoelectric conversion apparatus of the second embodiment.

First Modification

In the first and second embodiments, each light-shielding member is formed by filling a trench with a metal material. This results in the light-shielding member and the trench having substantially the same shape, except for the insulating material provided between them. However, it is not necessary for the light-shielding members 106 and 107 of the first embodiment or the light-shielding members 111 and 112 of the second embodiment to have the same shape as the trenches.

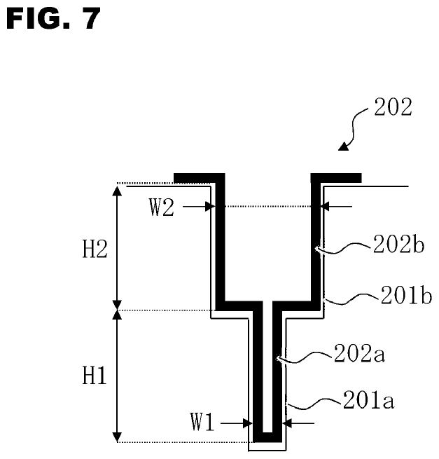

FIG. 7 is a diagram showing the structure of a light-shielding member 202 of the first modification. The light-shielding member 202 of this modification includes a first section 202a, which is formed with a predetermined thickness along the side walls of a first trench 201a, and a second section 202b, which is formed with a predetermined thickness along the side walls of a second trench 201b. This structure still allows the light-shielding member 202 to block light.

The first and second sections 202a and 202b are made of a metal material such as tungsten, aluminum, and copper. A dielectric material (insulating material) may be provided between the light-shielding members 202a and 202b and the surfaces defining the trenches 201a and 201b. The first and second sections 202a and 202b may have the same thickness. The area defined by the first section 202a and the area defined by the second section 202b may be hollow or filled with a dielectric material (insulating material). In this case, the light-shielding members 202a and 202b are located between the semiconductor substrate 53 and the dielectric materials (insulating material) in the trenches 201a and 201b.

In this modification, the first section 202a of the light-shielding member 202 is formed in the first trench 201a. The width W1 of the first section 202a is defined as the dimension including the width of the area that is hollow or filled with a different material as shown. The same applies to the width W2 of the second section 202b.

### Third Embodiment

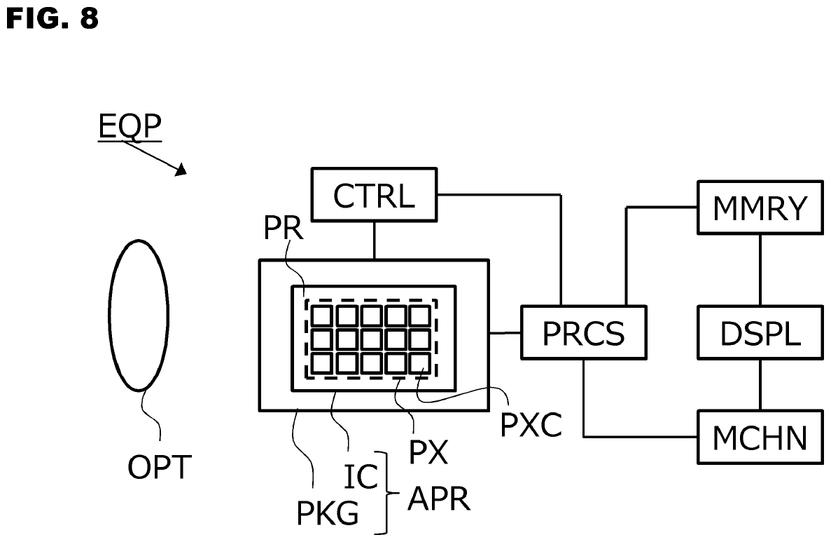

FIG. 8 is a schematic view illustrating a semiconductor apparatus APR of the third embodiment. The semiconductor apparatus APR includes a semiconductor device IC and may also include a package PKG for mounting the semiconductor device IC. In the present embodiment, the semiconductor apparatus APR is a photoelectric conversion apparatus (solid state imaging device) of the first or second embodiment. The semiconductor device IC has a pixel region PX, in which pixel circuits PXC are arranged in a matrix, and a peripheral region PR around the pixel region PX. The peripheral region PR may include a peripheral circuit.

The semiconductor apparatus APR is included in equipment EQP. The equipment EQP may include at least one of an optical system OPT, a controller CTRL, a processor PRCS, a display device DSPL, a storage device MMRY, and a mechanical device MCHN.

In addition to the semiconductor device IC, the semiconductor apparatus APR may include a package PKG that contains the semiconductor device IC. The package PKG may include a base, to which the semiconductor device IC is fixed, a cover, which faces the semiconductor device IC and may be made of glass, and connection members, which may be bondwires or bumps for connecting terminals of the base to terminals of the semiconductor device IC.

The equipment EQP may include at least one of an optical system OPT, a controller CTRL, a processor PRCS, a display device DSPL, a storage device MMRY, and a mechanical device MCHN. The optical system OPT forms an image on the semiconductor apparatus APR. The optical system OPT may be a lens, a shutter, or a mirror, for example. The controller CTRL controls the semiconductor apparatus APR. The controller CTRL may be a photoelectric conversion apparatus such as an ASIC.

The processor PRCS processes the signal output from the semiconductor apparatus APR. The processor PRCS may be a photoelectric conversion apparatus, such as a CPU or an ASIC, for an analog front end (AFE) or a digital front end (DFE). The display device DSPL may be an EL display device or a liquid crystal display device that displays the information (image) obtained by the semiconductor apparatus APR. The storage device MMRY may be a magnetic device or a semiconductor device that stores the information (image) obtained by the semiconductor apparatus APR. The storage device MMRY may be a volatile memory such as an SRAM or a DRAM, or a non-volatile memory such as a flash memory or a hard disk drive.

The mechanical device MCHN has a movable portion or a propulsion portion such as a motor or an engine. In the equipment EQP, the signal output from the semiconductor apparatus APR is displayed on the display device DSPL or transmitted to the outside by a communication device (not shown) of the equipment EQP. As such, the equipment EQP preferably includes the storage device MMRY and the processor PRCS in addition to the storage circuit and the arithmetic circuit of the semiconductor apparatus APR. The mechanical device MCHN may be controlled based on the signal output from the semiconductor apparatus APR.

The equipment EQP is suitable for electronic equipment such as an information terminal with a photographing function (e.g., a smartphone or a wearable terminal) and a camera (e.g., a camera with interchangeable lens, a compact camera, a video camera, and a surveillance camera). The mechanical device MCHN in a camera may drive the components of the optical system OPT for zooming, focusing, and shutter operation.

The equipment EQP may be transportation equipment such as a vehicle, a ship, or an air vehicle. The mechanical device MCHN in transportation equipment can be used as a moving device. The equipment EQP as transportation equipment is suitable to transport the semiconductor apparatus APR, and to assist and/or automate the driving (maneuvering) using an imaging function. The processor PRCS for assisting and/or automating driving (maneuvering) may perform a process for operating the mechanical device MCHN as a moving device based on the information obtained by the semiconductor apparatus APR. Alternatively, the equipment EQP may be medical equipment such as an endoscope, measuring equipment such as a distance measuring sensor, analyzing equipment such as an electron microscope, or office equipment such as a copying machine.

### OTHER EXAMPLES

A program that implements at least one of the functions of the embodiments described above may be installed in a system or an apparatus via a network or a storage medium. The present invention may be embodied as a process in which at least one processor of the computer of the system or the apparatus reads and runs the program. Further, the present invention may be embodied by circuitry (e.g., an ASIC) that implements at least one of the functions.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

The embodiments described above can be modified as appropriate without departing from the technical idea. In addition, the disclosure of the embodiments encompasses not only the items specified herein but also all items that may be recognized from the descriptions in this specification and the drawings attached to this specification.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-213317, filed on Nov. 26, 2019, which is hereby incorporated by reference herein in its entirety.

What is claimed is:

1. A photoelectric conversion apparatus comprising:
a semiconductor layer having a pixel region including a photoelectric conversion unit; and
a light-shielding member disposed in the pixel region, wherein
the semiconductor layer has a main surface and a trench continuous with the main surface, the main surface including a light-receiving surface of the photoelectric conversion unit,
the light-shielding member is disposed in the trench,
the light-shielding member includes a first section and a second section that is closer to the main surface than the first section,
the second section has a width that is greater than a width of the first section, and
the second section has a height that is greater than the width of the first section.

2. The photoelectric conversion apparatus according to claim 1, wherein a ratio of a height of the first section to the width of the first section is greater than a ratio of the height of the second section to the width of the second section.

3. The photoelectric conversion apparatus according to claim 1, wherein
the pixel region of the semiconductor layer further includes a charge holding portion configured to hold charges transferred from the photoelectric conversion unit, and
the first section is disposed between the photoelectric conversion unit and the charge holding portion.

4. The photoelectric conversion apparatus according to claim 3, wherein
a distance between a center of the first section and the photoelectric conversion unit is smaller than a distance between a center of the second section and the photoelectric conversion unit.

5. The photoelectric conversion apparatus according to claim 3, wherein
a side surface of the first section that faces toward the photoelectric conversion unit is flush with a side surface of the second section that faces toward the photoelectric conversion unit.

6. The photoelectric conversion apparatus according to claim 3, wherein
the second section is formed to cover at least a part of a side of the charge holding portion that faces toward the main surface.

7. The photoelectric conversion apparatus according to claim 3, wherein
the charge holding portion comprises a first charge holding portion configured to hold charges transferred from the photoelectric conversion unit and a second charge holding portion configured to store charges transferred from the first charge holding portion, and
the first section is disposed between the photoelectric conversion unit and the first charge holding portion.

8. The photoelectric conversion apparatus according to claim 1, wherein
the pixel region of the semiconductor layer includes a first charge holding portion configured to hold charges transferred from the photoelectric conversion unit and a second charge holding portion configured to store charges transferred from the first charge holding portion, and
the first section is disposed between the first charge holding portion and the second charge holding portion.

9. The photoelectric conversion apparatus according to claim 8, wherein the second section is formed to cover at least a part of at least one of the first charge holding portion and the second charge holding portion, the part being on a side facing toward the main surface.

10. The photoelectric conversion apparatus according to claim 1, wherein the width of the first section is at least 0.05 μm and not more than 0.15 μm.

11. The photoelectric conversion apparatus according to claim 1, wherein the first section and the second section are made of a same metal material.

12. The photoelectric conversion apparatus according to claim 1, wherein the first section and the second section are primarily composed of any of copper, tungsten, and aluminum.

13. The photoelectric conversion apparatus according to claim 1, wherein an insulating material is disposed between the light-shielding member and the semiconductor layer.

14. The photoelectric conversion apparatus according to claim 1, wherein
a dielectric material is disposed in the trench, and
the light-shielding member is disposed between the dielectric material and the semiconductor layer.

15. Equipment comprising:
the photoelectric conversion apparatus according to claim 1; and
at least one of following six components:
an optical system configured to form an image on the photoelectric conversion apparatus;
a controller configured to control the photoelectric conversion apparatus;
a processor configured to process a signal output from the photoelectric conversion apparatus;
a display device configured to display information obtained by the photoelectric conversion apparatus;
a storage device configured to store information obtained by the photoelectric conversion apparatus; and
a mechanical device including a movable portion or a propulsion portion.

16. A method for manufacturing a photoelectric conversion apparatus, the method comprising the steps of:
forming a trench by etching a semiconductor layer from a main surface side of the semiconductor layer, the semiconductor layer having a pixel region including a photoelectric conversion unit; and
embedding a metal material in the trench, wherein
the trench includes a first trench and a second trench that is disposed on the main surface side of the first trench,
the second trench has a width that is greater than a width of the first trench, and
the second trench has a height that is greater than the width of the first trench.

17. The method for manufacturing a photoelectric conversion apparatus according to claim 16, wherein the step of forming the trench includes
a first step of etching the main surface of the semiconductor layer to a width and a depth that are equal to the width and a depth of the first trench; and
a second step of etching a region including a trench formed in the first step to a width that is equal to the width of the second trench and to a depth that is equal to a depth of the second trench.

18. The method for manufacturing a photoelectric conversion apparatus according to claim 16, wherein the step of forming the trench includes
a step of forming the second trench; and
a step of forming the first trench on a bottom surface of the second trench.

19. A method for manufacturing a photoelectric conversion apparatus, the method comprising the steps of:
forming a trench by etching a semiconductor layer from a main surface side of the semiconductor layer, the semiconductor layer having a pixel region including a photoelectric conversion unit; and
embedding a metal material in the trench, wherein
the trench includes a first trench and a second trench that is disposed on the main surface side of the first trench, and
the step of forming the trench includes
a step of forming the second trench; and
a step of forming the first trench on a bottom surface of the second trench.
